(19) United States
(12) Patent Application Publication
(10) Pub. No.: US 2008/0169025 A1
(43) Pub. Date: Jul. 17, 2008

(54) DOPING TECHNIQUES FOR GROUP IBIIIAVIA COMPOUND LAYERS

(76) Inventors: Bulent M. Basol, Manhattan Beach, CA (US); Serdar Aksu, Santa Clara, CA (US); Yuriy Matus, Pleasanton, CA (US)

Correspondence Address: PILLSBURY WINTHROP SHAW PITTMAN LLP, P.O. BOX 10500, MCLEAN, VA, 22102, US

(21) Appl. No.: 11/852,980

(22) Filed: Sep. 10, 2007

Related U.S. Application Data
(60) Provisional application No. 60/870,827, filed on Dec. 19, 2006.
(60) Provisional application No. 60/869,276, filed on Dec. 8, 2006.

(51) Int. Cl. H01L 31/0272; H01L 31/04

(52) U.S. Cl. 136/262; 136/264; 438/84; 136/252; 257/E31.008

(57) ABSTRACT

A method of forming a doped Group IBIIIAVIA absorber layer for solar cells by reacting a a metallic precursor layer with a dopant structure. The metallic precursor layer including Group IB and Group IIIA materials such as Cu, Ga and In are deposited on a base. The dopant structure is formed on the metallic precursor layer, wherein the dopant structure includes a stack of one or more Group VIA material layers such as Se layers and one or more a dopant material layers such as Na.

### CROSS REFERENCE TO RELATED APPLICATIONS

This application claims the benefit of U.S. Provisional App. No. 60/870,827 filed Dec. 19, 2006 entitled “Doping Techniques for Group IBIIIAVIA Compound Layers” and claims the benefit of U.S. Provisional App. No. 60/869,276 filed Dec. 8, 2006 entitled “Doping Approaches for Group IBIIIAVIA Compound Layers”, and incorporates each herein by reference.

### BACKGROUND OF THE INVENTION

1. Field of the Invention

The present invention relates to methods for preparing thin films of doped semiconductors for photovoltaic applications.

2. Description of the Related Art

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ(SySe_{1-y})ₖ, where 0≦x≦1, 0≦y≦1 and k is approximately 2, have already been employed in solar cell structures that yielded conversion efficiencies approaching 20%. Among the family of compounds, best efficiencies have been obtained for those containing both Ga and In, with a Ga amount in the 15-25%. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications.

The structure of a conventional Group IBIIIAVIA compound photovoltaic cell such as a Cu(In,Ga,Al)(S,Se,Te)₂ thin film solar cell is shown in FIG. 1. The device 10 is fabricated on a base 20 comprising a substrate 11, such as a sheet of glass, a sheet of metal, an insulating foil or web, or a conductive foil or web and a conductive layer 13. The absorber film 12, which comprises a material in the family of Cu(In,Ga,Al)(S,Se,Te)₂, is grown over the conductive layer 13 or the contact layer, which is previously deposited on the substrate 11 and which acts as the electrical ohmic contact to the device. The most commonly used contact layer or conductive layer in the solar cell structure of FIG. 1 is Molybdenum (Mo). If the substrate itself is a properly selected conductive material such as a Mo foil, it is possible not to use a conductive layer 13, since the substrate 11 may then be used as the ohmic contact to the device. The conductive layer 13 may also act as a diffusion barrier in case the metallic foil is reactive. For example, metallic foils comprising materials such as Al, Ti, Ni, Cu may be used as substrates provided a barrier such as a Mo layer is deposited on them protecting them from Se or S vapors. The barrier is often deposited on both sides of the foil to protect it well. After the absorber film 12 is grown, a transparent layer 14 such as a CdS, ZnO or CdS/ZnO stack is formed on the absorber film. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side. A variety of materials, deposited by a variety of methods, can be used to provide the various layers of the device shown in FIG. 1. It should be noted that although the chemical formula of copper indium gallium sulfo-selenide is often written as Cu(In,Ga)(S,Se)₂, a more accurate formula for the compound is Cu(In,Ga)(S,Se)ₖ, where k is typically close to 2 but may not be exactly 2. For simplicity we will continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The first technique that yielded high-quality Cu(In,Ga)Se₂ films for solar cell fabrication was co-evaporation of Cu, In, Ga and Se onto a heated substrate in a vacuum chamber. This is an approach with low materials utilization and high cost of equipment.

Another technique for growing Cu(In,Ga)(S,Se)₂ type compound thin films for solar cell applications is a two-stage process where metallic components of the Cu(In,Ga)(S,Se)₂ material are first deposited onto a substrate, and then reacted with S and/or Se in a high temperature annealing process. For example, for CuInSe₂ growth, thin layers of Cu and In are first deposited on a substrate and then this stacked precursor layer is reacted with Se at elevated temperature. If the reaction atmosphere also contains sulfur, then a CuIn(S,Se)₂ layer can be grown. Addition of Ga in the precursor layer, i.e. use of a Cu/IN/Ga stacked film precursor, allows the growth of a Cu(In,Ga)(S,Se)₂ absorber.

Sputtering and evaporation techniques have been used in prior art approaches to deposit the layers containing the Group IB and Group IIIA components of the precursor stacks. In the case of CuInSe₂ growth, for example, Cu and In layers were sequentially sputter-deposited on a substrate and then the stacked film was heated in the presence of gas containing Se at elevated temperature for times typically longer than about 30 minutes, as described in U.S. Pat. No. 4,798,660. More recently U.S. Pat. No. 6,048,442 disclosed a method comprising sputter-depositing a stacked precursor film comprising a Cu-Ga alloy layer(s) and an In layer to form a Cu—Ga/In stack on a metallic back electrode layer and then reacting this precursor stack film with one of Se and S to form the absorber layer. U.S. Pat. No. 6,092,669 described sputtering-based equipment for producing such absorber layers.

One prior art method described in U.S. Pat. No. 4,581,108 utilizes a low cost electrodeposition approach for metallic precursor preparation. In this method a Cu layer is first electrodeposited on a substrate covered with Mo. This is then followed by electrodeposition of an In layer and heating of the deposited Cu/In stack in a reactive atmosphere containing Se to obtain CIS. Prior research on possible dopants for Group IBIIIAVIA compound layers has shown that alkali metals, such as Na, K, and Li, affect the structural and electrical properties of such layers. Especially, inclusion of Na in CIGS layers was shown to be beneficial for their structural and electrical properties and for increasing the conversion efficiencies of solar cells fabricated on such layers provided that its concentration is well controlled. Beneficial effects of Na on CIGS layers were recognized in early 1990s (see for example, J. Hedstrom et al., “ZnO/CdS/CIGS thin film solar cells with improved performance”, Proceedings of IEEE PV Specialists Conf., 1993, p. 364; M. Bodegard et al., “The influence of sodium on the grain structure of CIS films for PV applications”, Proceedings of the 12^{th} European Photovoltaic Solar Energy Conference, April-1994. p. 1743; and J. Holz et al. “The effect of substrate impurities on the electronic conductivity in CIS thin films”, Proceedings of the 12^{th} European Photovoltaic Solar Energy Conference, April-1994. p. 1592). Inclusion of Na into CIGS layers was achieved by various ways. For example, Na was diffused into the CIGS layer from the substrate if the CIGS film was grown on a Mo contact layer deposited on a Na-containing soda-lime glass substrate. This approach, however, is hard to control and reportedly causes non-uniformities in the CIGS layers depending on how much Na diffuses from the substrate through the Mo contact layer. Therefore the amount of Na doping is a strong function of the nature of the Mo layer such as its grain size, crystalline structure, chemical composition, thickness, etc. In another approach (see for example, U.S. Pat. No. 5,994,163 and U.S. Pat. No. 5,626,688), Na is included in the CIGS layers intentionally, in a specific manner. In one approach, a diffusion barrier is deposited on the soda-lime glass substrate to stop possible Na diffusion from the substrate into the absorber layer. A Mo contact film is then deposited on the diffusion barrier. An interfacial layer comprising Na is formed on the Mo surface. The CIGS film is then grown over the Na containing interfacial layer. During the growth period, Na from the interfacial layer gets included into the CIGS layer and dopes it. Therefore, this approach uses a structure where the source of Na is under the growing CIGS layer at the interface between the growing CIGS layer and the Mo contact. The most commonly used interfacial layer material is NaF, which is deposited on the Mo surface before the deposition of the CIGS layer by the co-evaporation technique (see, for example, Granath et al., Solar Energy Materials and Solar Cells, vol: 60, p: 279 (2000)). It should be noted that effectiveness of a Na-diffusion barrier for limiting Na content of a CIGS layer was also disclosed in the papers by M. Bodegard et al., and J. Holz et al., cited above.

U.S. Pat. No. 7,018,858 describes a method of fabricating a layer of CIGS wherein an alkali layer is formed on the back electrode (typically Mo) by dipping the back electrode in an aqueous solution containing alkali metals, drying the layer, forming a precursor layer on the alkali layer and heat treating the precursor in a selenium atmosphere. The alkali film formed by the wet treatment process on the Mo electrode layer is said to contain moisture and therefore it is stated that it can be free from such troubles that a dry film formed by a dry process may run into, such as absorbing moisture from the surrounding air with the result of deteriorating and the peeling of the layer. The hydration is claimed to enable the alkali film to keep moisture that can be regulated by the baking or drying treatment.

Another method of supplying Na to the growing CIGS layer is depositing a Na-doped Mo layer on the substrate, and following this step by deposition of an un-doped Mo layer and growing the CIGS film over the undoped Mo layer. In this case Na from the Na-doped Mo layer diffuses through the undoped Mo layer and enters the CIGS film during high temperature growth (J. Yun et al., Proc. 4^{th} World Conf. PV Energy Conversion, p. 509, IEEE, 2006). Various strategies of including Na in CIGS type absorbers are summarized in a recent publication by Rudmann et al., (Thin Solid Films, vol. 480-481, p. 55, 2005). These approaches are categorized into two main approaches; i) deposition of a Na-bearing interface film over the contact layer followed by CIGS layer growth over the Na-bearing interface film, and ii) formation of a CIGS layer on a Na-free base followed by deposition of a Na-bearing film on the CIGS compound layer and high temperature annealing to drive the Na into the already formed CIGS compound layer.

### SUMMARY OF THE INVENTION

The present invention provides a process to introduce one or more dopant materials into absorbers used for manufacturing solar cells. In a first stage of the inventive process, a substantially metallic precursor is prepared. The substantially metallic precursor is formed as a stack of material layers. In a second stage, a pre-absorber structure is formed by forming a dopant structure, including at least one or more layers of a dopant material with or without another material layer or layers, on the substantially metallic precursor. In a third stage, annealing of the pre-absorber structure forms a doped absorber.

Accordingly, in one aspect of the present invention, a multilayer structure to form doped absorber layers for solar cells is provided. The multilayer structure includes a base comprising a substrate layer, a substantially metallic precursor layer formed on the base, and a dopant structure including a dopant material formed on the substantially metallic precursor layer. The substantially metallic precursor layer includes Group IB and IIIA elements while the dopant structure includes Group VIA elements. The dopant structure includes either a layer of dopant material or a dopant carrier layer or a dopant stack. The dopant stack includes one or more layers of dopant material and one or more layers of Group VIA elements stacked in preferred orders. In another aspect of the present invention, a process of forming a doped Group IBIIIAVIA absorber layer on a base is provided. The process includes depositing a substantially metallic precursor layer on the base, forming a dopant structure on the precursor layer, reacting the precursor layer and the dopant structure to form the absorber layer. Accordingly, the substantially metallic precursor layer includes Group IB and Group IIIA materials, and the dopant structure includes a Group VIA material and a dopant material selected from the group consisting of Na, K and Li.

### BRIEF DESCRIPTION OF THE DRAWINGS

FIG. 1 is a schematic cross-sectional view of a solar cell employing a Group IBIIIAVIA absorber layer;

FIG. 2A is a schematic illustration of a pre-absorber structure of the present invention including a dopant layer formed on a precursor layer;

FIG. 2B is a schematic illustration of an absorber layer formed after reacting the pre-absorber structure shown in FIG. 2A;

FIG. 3A is a schematic illustration of a pre-absorber structure of the present invention including a dopant stack formed on a precursor layer;

FIG. 3B is a schematic illustration of an absorber layer formed after reacting the pre-absorber structure shown in FIG. 3A;

FIG. 4A is a schematic illustration of a pre-absorber structure of the present invention including a dopant stack formed on a precursor layer;

FIG. 4B is a schematic illustration of an absorber layer formed after reacting the pre-absorber structure shown in FIG. 4A;

FIG. 5A is a schematic illustration of a pre-absorber structure of the present invention including a dopant stack formed on a precursor layer;

FIG. 5B is a schematic illustration of an absorber layer formed after reacting the pre-absorber structure shown in FIG. 5A;

FIG. 6A is a schematic illustration of a pre-absorber structure of the present invention including a dopant carrying layer formed on a precursor layer;

FIG. 6B is a schematic illustration of an absorber layer formed after reacting the pre-absorber structure shown in FIG. 6A;

FIG. 7 is a schematic illustration of a solar cell manufactured using an embodiment of the present invention;

FIG. 8A illustrates I-V characteristics of a solar cell fabricated on a CIGS absorber layer doped in accordance with one embodiment of the present invention;

FIG. 8B illustrates I-V characteristics of a solar cell fabricated on an un-doped CIGS absorber layer;

FIG. 9A is a SEM picture showing surface of a CIGS absorber which has been formed using an embodiment of the present invention; and

FIG. 9B is a SEM picture showing surface of a CIGS absorber which has been formed using an embodiment of the present invention.

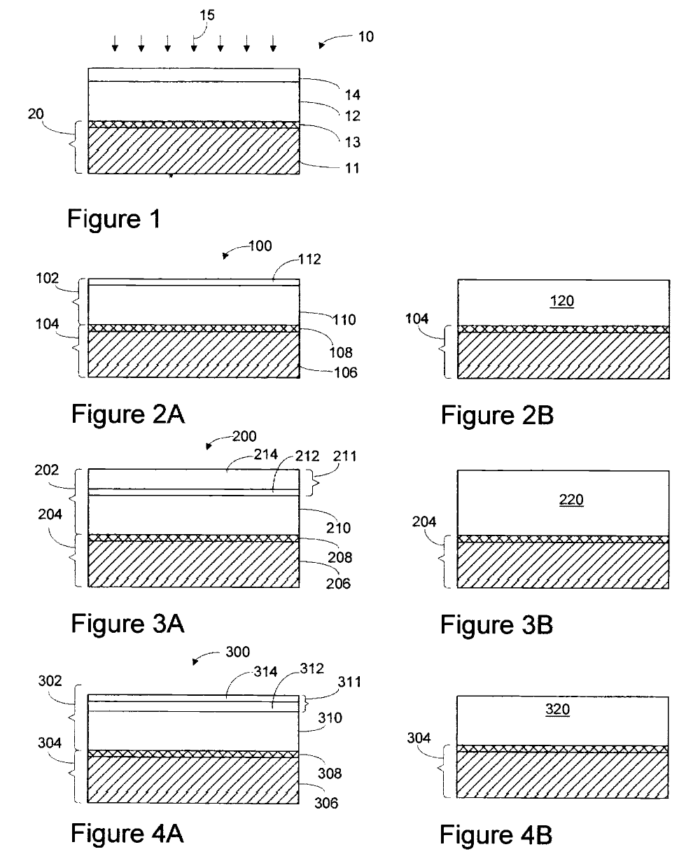

### DETAILED DESCRIPTION

The present invention provides a process to introduce one or more dopant materials into a precursor layer to manufacture absorber layers for solar cells. The process of the present invention generally includes three stages. In a first stage of the inventive process a primary structure such as a precursor layer is initially prepared. The precursor layer may be formed as a stack including layers of materials. In a second stage of the present invention, a secondary structure or a dopant structure including at least one or more layers of a dopant material with or without another material layer or layers is formed on the precursor layer. The primary and secondary structures together form a pre-absorber structure or pre-absorber stack. And, in a third stage, annealing of the pre-absorber structure forms a doped absorber layer or, in the art as often referred to as, a doped compound layer.

Although in the following, the present invention will be exemplified by a process for doping Group IBIIIAVIA compound layers for solar cell absorbers, the same principles may be used to dope any other layer to manufacture absorbers or any other purpose device. Accordingly, exemplary dopant materials may preferably be a Group IA material such as Na, K, Li, a Group IIA material or a Group VA material or any other possible dopant materials used in the semiconductor industry. In the following embodiments, the precursor layer or the precursor stack used may preferably be a substantially metallic precursor stack or layer. It should be noted that the “substantially metallic precursor” means the precursor is substantially made of Group IB materials, such as Cu, and Group IIIA materials such as Ga, In. A substantially metallic precursor may for example include one or more metallic phases comprising elemental metallic layers, and/or mixtures of metals such as Cu, In and Ga and/or their alloys such as Cu-Ga binary alloys, Cu—In binary alloys, Ga—In binary alloys and Cu—Ga—In ternary alloys. These metals and alloys may form about 100% metallic precursor phase if no Group VIA element, such as Se, is included in the constitution of the precursor. The precursor may additionally contain Group VIA materials such as Se, however, in this case the Group VIA/(Group IB+Group IIIA) molar ratio should be less than about 0.5, preferably less than about 0.2, i.e. the Group IB and/or Group IIIB materials should not be fully reacted with the Group VIA materials. This ratio in a fully reacted and formed Group IBIIIAVIA compound is typically equal to or larger than 1. In above given exemplary molar ratios, a precursor layer with a molar ratio of 0.5 corresponds to 50% metallic and 50% non-metallic (such as Se) phase. In this respect, a precursor layer with a molar ratio of 0.2 includes 80% metallic phase and 20% non-metallic phase such as non-metallic Se phase. Various embodiments of the present invention will now be described in connection with FIGS. 2A-6B. In the following figures, various schematic illustrations of multilayer structures, representing various embodiments, are exemplified in side or cross-sectional views. Dimensions of the various layers are exemplary and are not drawn to scale.

As shown in FIG. 2A, in one embodiment, a multilayer stack 100 of the present invention includes a pre-absorber structure 102 formed on a base 104 including a substrate 106 and a contact layer 108. The pre-absorber structure 102 includes a precursor layer 110 and a dopant structure 112 comprising essentially a dopant bearing-film which is formed on top of the precursor layer 110. The dopant-bearing film 112 may be 2-100 nm thick, preferably 5-20 nm thick. In this embodiment, the precursor layer 110 may comprise at least one Group IB material and at least one Group IIIA material, which are deposited on the dopant-free base 104 forming a substantially metallic precursor layer. At least one dopant-bearing film 112 is then deposited over the metallic precursor layer 110 to complete the pre-absorber structure 102, which is a “metallic precursor/dopant-bearing film” stack. As shown in FIG. 2B, once completed, the multilayer stack 100 is heated up, optionally in presence of additional gaseous Group VIA material species to transform the pre-absorber stack 102 into an absorber layer 120 comprising a doped Group IBIIIAVIA semiconductor layer. During this reaction stage, the multilayer stack 100 may be annealed at a temperature range of 400-600 C for a period of time of about 5-60 minutes, preferably 10-30 minutes. Alternatively, in another embodiment, the precursor layer 110 may comprise at least one Group IB material, at least one Group IIIA material and at least one Group VIA material, which are deposited on the dopant-free base 104. The rest of the process is performed as described above to form the doped Group IBIIIAVIA semiconductor layer 120 shown in FIG. 2B. During this reaction stage, the multilayer stack 100 may be annealed at a temperature range of 400-600 C. for a period of time of about 5-60 minutes, preferably 10-30 minutes.

As shown in FIG. 3A, in another embodiment, a multilayer stack 200 of the present invention includes a pre-absorber structure 202 formed on a base 204 including a substrate 206 and a contact layer 208. The pre-absorber structure 202 includes a precursor layer 210 and a dopant structure 211, which is essentially a dopant stack in this embodiment, including a first and second layers 212 and 214, respectively, which are formed on top of the precursor layer 210. Accordingly the first layer 212 is a dopant-bearing film comprising a Group IA material such as Na, K or Li, a Group IIA material or a Group VA material. The second layer 214, which is a cap layer for the first layer 212, comprises a Group VIA material such as Se. The dopant-bearing film 212 may be 2-100 nm thick, preferably 5-20 nm thick. The cap layer 214 may be 200-2000 nm thick, preferably 500-1500 nm tick. In this embodiment, the precursor layer 210 may comprise at least one Group IB material, and at least one Group IIIA material, which are deposited on the dopant-free base 204 forming a substantially metallic precursor layer. At least one first layer 212 or dopant-bearing film is then deposited over the metallic precursor layer 210 forming a “metallic precursor/dopant-bearing film” stack. Subsequently, at least one second layer 214 or cap layer which may comprise a Group VIA material is then deposited over the dopant-bearing film 212 to complete the pre-absorber structure 202, which is a “metallic precursor/dopant-bearing film/Group VIA material layer” stack. As shown in FIG. 3B, the multilayer stack 200 is heated up to transform the pre-absorber stack 202 into an absorber layer 220 comprising a doped Group IBIIIAVIA semiconductor layer. Additional Group VIA material species may be present during the heating period. During this reaction stage, the multilayer stack 200 may be annealed at a temperature range of 400-600 C. for a period of time of about 5-60 minutes, preferably 10-30 minutes.

As shown in FIG. 4A, in another embodiment, a multilayer stack 300 of the present invention includes a pre-absorber structure 302 formed on a base 304 including a substrate 306 and a contact layer 308. The pre-absorber structure 302 includes a precursor layer 310 and a dopant structure 311, which is essentially a dopant stack in this embodiment, including a first and second layers 312 and 314, respectively, which are formed on top of the precursor layer 310. Accordingly, the first layer 312, which is essentially a buffer layer for the second layer 314, comprises a Group VIA material. The second layer 314 is a dopant-bearing film comprising a Group IA material such as Na, K or Li, a Group IIA material or a Group VA material. The buffer layer 312 may be 50-500 nm thick, preferably 100-300 nm thick. The dopant-bearing film 314 may be 2-100 nm thick, preferably 5-20 nm thick. In this embodiment, the precursor layer 310 may comprise at least one Group IB material, and at least one Group IIIA material, which are deposited on the dopant-free base 304 forming a substantially metallic precursor layer. At least one first layer 312 or a buffer layer comprising a Group VIA material is deposited over the metallic precursor layer 310 forming a “metallic precursor/Group VI material layer” stack. Subsequently, at least one second layer 314 which is a dopant-bearing film is then deposited on the Group VI material layer to complete the pre-absorber structure 302, which is a “metallic precursor/Group VIA material layer/dopant-bearing film/” stack. As shown in FIG. 4B, the multilayer stack 300 is heated up to transform the pre-absorber stack 302 into an absorber layer 320 comprising a doped Group IBIIIAVIA semiconductor layer. Additional Group VIA material species may be present during the heating period. During this reaction stage, the multilayer stack 300 may be annealed at a temperature range of 400-600 C. for a period of time of about 5-60 minutes, preferably 10-30 minutes.

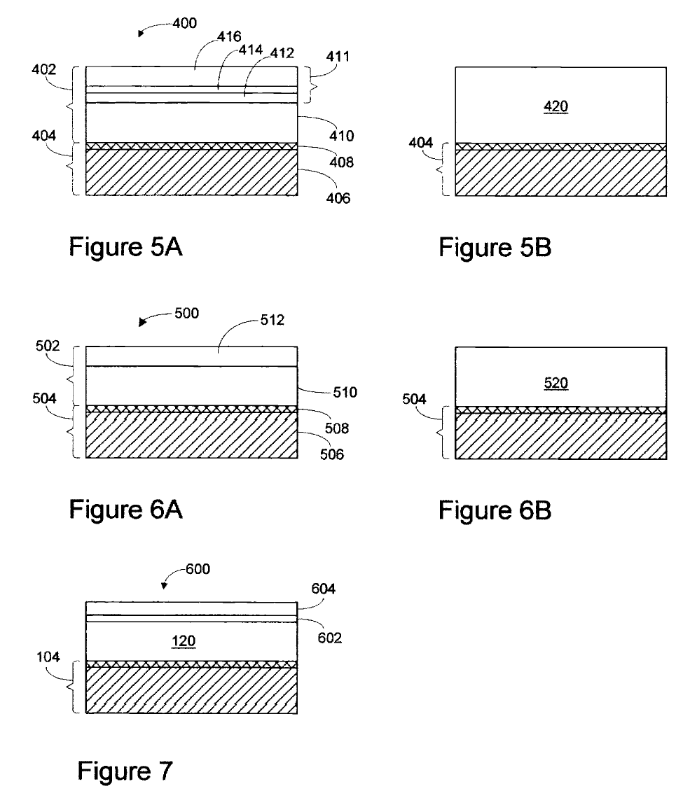

As shown in FIG. 5A, in another embodiment, a multilayer stack 400 of the present invention includes a pre-absorber structure 402 formed on a base 404 including a substrate 406 and a contact layer 408. The pre-absorber structure 402 includes a precursor layer 410 and a dopant structure 411, which is essentially a dopant stack in this embodiment, including a first, second and third layers 412, 414 and 416, respectively, which are formed on top of the precursor layer 410. Accordingly the first and third layers 412 and 416, which are essentially a buffer layer and a cap layer, respectively, for the second layer, comprise a Group VIA material. The second layer 414, which is a dopant-bearing film sandwiched between the first and third layers, comprises a Group IA material such as Na, K or Li, a Group IIA material or a Group VA material. The buffer layer 412 may be 50-500 nm thick, preferably 100-300 nm thick. The dopant-bearing film 414 may be 2-100 nm thick, preferably 5-20 nm thick. The cap layer 416 may be 200-2000 nm thick, preferably 500-1500 nm thick. In this embodiment, the precursor layer 410 may comprise at least one Group IB material, and at least one Group IIIA material, which are deposited on the dopant-free base 404 forming a substantially metallic precursor layer. At least one first layer 412 or a buffer layer which may comprise a Group VIA material is then deposited over the metallic precursor layer forming a “metallic precursor/Group VIA material layer” stack. In the following step, at least one second layer 414 or dopant-bearing film is then deposited over the Group VIA material layer forming a “metallic precursor/Group VIA material layer/dopant-bearing film” stack. Finally, at least one third layer 416 or a cap layer which may comprise a Group VIA material is then deposited over the dopant-bearing film 414 to complete the pre-absorber structure 402, which is a “metallic precursor/Group VIA material layer/dopant-bearing film/Group VIA material layer” stack. As shown in FIG. 5B, the multilayer stack 400 is heated up to transform the pre-absorber stack 402 into an absorber layer 420 comprising a doped Group IBIIIAVIA semiconductor layer. Additional Group VIA material species may be present during the heating period. In this embodiment, although the dopant stack is exemplified with three layers, stacks with more than three layers, while at least one being the dopant bearing layer, may be used. During this reaction stage, the multilayer stack 400 may be annealed at a temperature range of 400-600 C. for a period of time of about 5-60 minutes, preferably 10-30 minutes. As shown in FIG. 6A, in one embodiment, a multilayer stack 500 of the present invention includes a pre-absorber structure 502 formed on a base 504 including a substrate 506 and a contact layer 508. The pre-absorber structure 502 includes a precursor layer 510 and a dopant structure 512, which is essentially a dopant carrier layer, comprising a doped Group VIA material layer which is formed on top of the precursor layer 510. In the dopant carrier layer 512, the dopant species are held in the Group VI material matrix. The dopant carrier layer 512 may be 250-2600 nm thick, preferably 600-1800 nm thick. In this embodiment, the precursor layer 510 may comprise at least one Group IB material, and at least one Group IIIA material, which are deposited on a dopant-free base forming a substantially metallic precursor layer. At least one dopant is then deposited together with at least one Group VIA material layer over the metallic precursor layer forming a “metallic precursor/dopant-bearing Group VIA material layer” stack. As shown in FIG. 6B, the multilayer stack 500 is then heated up to transform the pre-absorber stack 502 into an absorber layer 520 comprising a doped Group IBIIIAVIA semiconductor layer. Additional Group VIA material species may be present during the heating period. During this reaction stage, the multilayer stack 500 may be annealed at a temperature range of 400-600 C. for a period of time of about 5-60 minutes, preferably 10-30 minutes. FIG. 7 shows a solar cell 600 by further processing any one of the above described absorber layers, for example, absorber layer 120 shown in FIG. 2B. Solar cells may be fabricated on the absorber layers of the present invention using materials and methods well known in the field. For example a thin CdS layer 602 may be deposited on the surface of the absorber layer 120 using the chemical dip method. A transparent window 604 of ZnO may be deposited over the CdS layer using MOCVD or sputtering techniques. A metallic finger pattern (not shown) is optionally deposited over the ZnO to complete the solar cell.

Although the invention may be practiced employing metallic precursor layers and layers of Group VIA materials formed by a variety of techniques such as sputtering, evaporation, ink deposition etc., it is especially suited for wet deposition techniques such as electrodeposition and electroless deposition. It should be noted that dopant-bearing layers such as NaF, NaCl, Na₂S, Na₂Se layers etc., are not conductors. Furthermore they are mostly soluble in solvents (such as water or organic liquids) used in electroplating and electroless plating baths or electrolytes. Therefore, the prior art approach of introducing a dopant into a Group IBIIIAVIA layer by depositing a dopant-bearing film over a base and growing the Group IBIIIAVIA layer over the dopant-bearing film presents problems. For example, if electroplating is used for the deposition of the Group IBIIIAVIA layer or for the deposition of a Group IB material, a Group IIIA material or a Group VIA material, such deposition may not be possible on a dopant-bearing film because the dopant-bearing film has very low electrical conductivity. Furthermore, as stated before, the dopant-bearing film may dissolve into the plating electrolyte(s). For electroless deposition techniques dopant-bearing film dissolution into the electroless deposition bath may also present a problem. The following description of the present invention will employ, as an example, an approach that utilizes electrodeposition to form doped Cu(In,Ga)(S,Se)₂ or CIGS(S) pre-absorber layers or compound layers. Other deposition techniques may also be utilized as stated before.

### EXAMPLE 1

A precursor layer may comprise more than one material layer formed on top of one another. A precursor layer may be formed by stacking layers of materials, for example, by electroplating Cu, In and Ga metal layers onto a base. The base may comprise a substrate and a conductive layer or a contact layer. The surface of the contact layer preferably comprises at least one of Ru, Os and Ir. Such prepared precursor stack may comprise at least one layer of Cu, In and Ga. The precursor stack may also comprise alloys or mixtures of Cu, In and Ga metal species and thereby metallic by nature. An exemplary precursor stack may be a Cu/Ga/Cu/In stack. Thicknesses of Cu, In and Ga may be selected in accordance with the desired final composition of the absorber layer, i.e., CIGS(S) layer.

Once the metallic precursor stack is prepared, a dopant structure including a dopant-bearing film is formed on the precursor stack. Accordingly, a dopant-bearing film such as a NaF film is deposited over the precursor stack or layer and the pre-absorber structure thus formed may be annealed in Se and/or S bearing atmosphere to form a doped absorber layer (CIGS(S) layer). The thickness of the dopant-bearing film may typically be in the range of 5-100 nm depending on the total thickness of the precursor stack. It is desirable to have the dopant amount to be 0.01-1% atomic in the final CIGS(S) layer. The dopant-bearing film may be deposited using various techniques such as evaporation, sputtering and wet deposition processes. Wet deposition approaches include spraying of a dopant bearing solution (such as an alcohol or water solution of NaF) onto the precursor stack, dipping the precursor stack into a dopant-bearing solution, or printing or doctor blading a dopant-bearing solution onto the precursor stack, followed by drying.

### EXAMPLE 2

A metallic precursor stack may be formed by electroplating Cu, In and Ga onto a base. The base may comprise a substrate and a conductive layer or a contact layer. The surface of the contact layer preferably comprises at least one of Ru, Os and Ir. The precursor stack may comprise at least one layer of Cu, In and Ga. The precursor stack may also comprise alloys or mixtures of Cu, In and Ga species. An exemplary precursor stack is a Cu/Ga/Cu/In stack. Thicknesses of Cu, In and Ga may be selected in accordance with the desired final composition of the absorber layer (CIGS(S) layer).

Once the precursor stack is prepared, a dopant structure including a dopant stack is formed on the precursor stack. The dopant stack includes a dopant-bearing film and a cap layer for the dopant-bearing film. Accordingly, a dopant-bearing film such as NaF may be deposited over the metallic precursor stack and at least one cap layer comprising Group VIA material (such as a Se) may be deposited over the dopant-bearing film. The pre-absorber structure thus formed is then annealed to form a doped absorber layer (CIGS(S) layer). There may be additional Group VIA gaseous species such as Se and/or S vapors H₂Se and/or H₂S present during the annealing process. The thickness of the dopant-bearing film may typically be in the range of 5-100 nm depending on the total thickness of the precursor stack. It is desirable to have the dopant amount to be 0.01-1% atomic in the final absorber layer. The dopant-bearing film may be deposited using various techniques such as evaporation, sputtering and wet deposition approaches. Wet deposition approaches include spraying of a dopant bearing solution (such as an alcohol or water solution of NaF) onto the precursor stack, dipping the precursor stack into a dopant-bearing solution, or printing or doctor blading a dopant-bearing solution onto the precursor stack, followed by drying. The cap layer including the Group VIA material such as the Se may be deposited by various techniques such as physical vapor deposition, electrodeposition, electroless deposition, ink deposition etc. The thickness of the cap layer may be in the range of 200-2000 nm depending on the original thickness of the precursor stack.

### EXAMPLE 3

A metallic precursor stack may be formed by electroplating Cu, In and Ga layers onto a base. The base may comprise a substrate and a conductive layer or a contact layer. The surface of the contact layer preferably comprises at least one of Ru, Os and Ir. The metallic precursor stack may comprise at least one layer of Cu, In and Ga. The metallic precursor stack may also comprise alloys or mixtures of Cu, In and Ga species. An exemplary metallic precursor stack may be a Cu/Ga/Cu/In stack. Thicknesses of Cu, In and Ga may be selected in accordance with the desired final composition of the absorber layer (CIGS(S) layer).

Once the precursor stack is prepared, a dopant structure including a dopant stack is formed on the precursor stack. The dopant stack includes a buffer layer for a dopant-bearing film and the dopant-bearing film. Accordingly, a buffer layer comprising a Group VIA material (such as a Se) may be deposited on the precursor stack and a dopant-bearing film such as NaF may be deposited over the Group VIA material layer. The pre-absorber structure thus formed is then annealed to form a doped absorber layer (CIGS(S) layer). There may be additional Group VIA gaseous species such as Se and/or S vapors H₂Se and/or H₂S present during the annealing process. The thickness of the buffer layer may be in the range of 50-500 nm. The thickness of the dopant-bearing film may typically be in the range of 5-100 nm depending on the total thickness of the precursor stack. It is desirable to have the dopant amount to be 0.01-1% atomic in the final absorber layer. The dopant-bearing film may be deposited using various techniques such as evaporation, sputtering and wet deposition approaches. Wet deposition approaches include spraying of a dopant bearing solution (such as an alcohol or water solution of NaF) onto the precursor stack, dipping the precursor stack into a dopant-bearing solution, or printing or doctor blading a dopant-bearing solution onto the precursor stack, followed by drying. The buffer layer comprising the Group VIA material such as the Se may be deposited by various techniques such as physical vapor deposition, electrodeposition, electroless deposition, ink deposition etc. It should be noted that in this approach the dopant does not directly contact the surface of the precursor stack. Instead, as the “precursor stack/buffer Group VIA material layer/dopant-bearing film” structure (see FIG. 4A) is heated to form the absorber layer (CIGS(S) compound) (see FIG. 4B), the dopant first mixes with the Group VIA material layer within the buffer and then gets included into the forming absorber layer. In that respect, the Group VIA material layer acts as the source of the dopant such as Na.

### EXAMPLE 4

A metallic precursor stack may be formed by electroplating Cu, In and Ga onto a base. The base may comprise a substrate and a conductive layer or a contact layer. The surface of the contact layer preferably comprises at least one of Ru, Os and Ir. The precursor stack may comprise at least one layer of Cu, In and Ga. The precursor stack may also comprise alloys or mixtures of Cu, In and Ga species. An exemplary precursor stack may be a Cu/Ga/Cu/In stack. Thicknesses of Cu, In and Ga layers may be selected in accordance with the desired final composition of the absorber layer (CIGS(S) layer).

Once the precursor stack is prepared, a dopant structure including a dopant carrier layer is formed on the precursor stack. Accordingly, a Group VIA material layer (such as a Se layer) comprising a dopant such as Na may be deposited on the precursor stack. The pre-absorber structure thus formed is then annealed to form a doped absorber layer. There may be additional Group VIA gaseous species such as Se and/or S vapors H₂Se and/or H₂S present during the annealing process. In one embodiment, to form the dopant carrier layer, a Group VIA material layer such as the Se layer may be deposited by various techniques such as physical vapor deposition, electrodeposition, electroless deposition, ink deposition etc on the precursor stack. In electrodeposition and electroless deposition techniques used to deposit Se, a dopant such as Na may be introduced into the plating baths, to be carried onto the precursor stack along with Se. For ink deposition, the dopant may be included in the ink formulation along with the Group VIA material. For physical deposition techniques, the dopant may be co-deposited with the Group VIA material(s) over the metallic precursor stack at low temperatures (typically room temperature) so that there is no substantial reaction between the precursor stack and the Group VIA material during the deposition of the Group VIA material.

As explained above, it is also possible to include dopant in the Group VIA material layer by forming one or more layers of “Group VIA material/dopant-bearing film” in dopant structure over the precursor. For example, a multilayer structure such as “base/metallic precursor stackibuffer Group VIA material layer/dopant-bearing film/cap Group VIA material layer” may be formed and then reacted as described above. In this example, the dopant stack of “Group VIA material/dopant-bearing film/Group VIA material” acts as the source of the dopant such as Na to the growing absorber layer (CIGS(S) compound layer). As in Example 3, during the annealing step, to form the absorber layer, the dopant first mixes with the Group VIA material and then gets included into the forming absorber layer. In all of the above examples, the substrate may be a flexible metallic substrate such as a steel web substrate having a thickness about 25-125 micrometers, preferably 50-75 micrometers. Similarly, the contact layer (Ru, Os or Ir) may be 200-1000 nm thick, preferably 300-500 nm thick. The above given precursor layers or stacks may have a thickness in the range of 400-1000 nm, preferably, 500-700 nm.

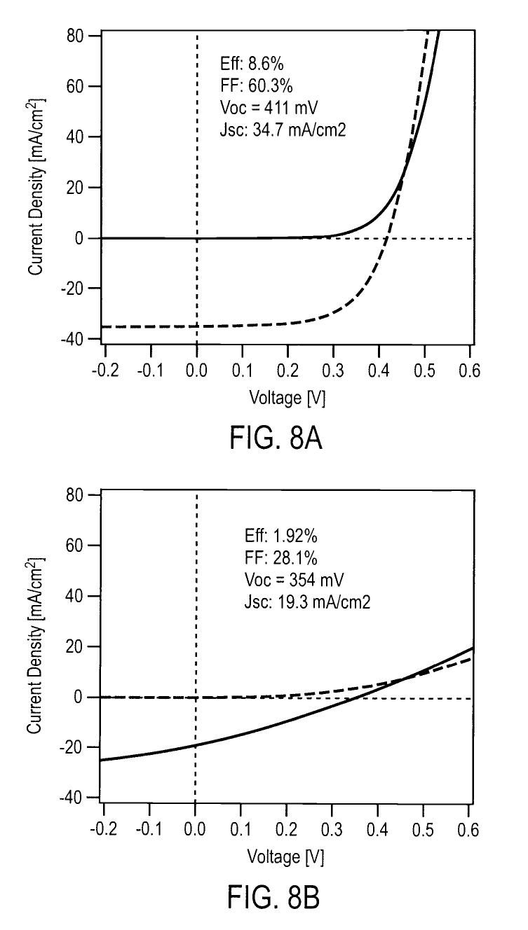

FIG. 8A shows the I-V characteristics of a solar cell fabricated on a absorber layer (CIGS layer) prepared using the general approach given in Example 2 above. The dopant-bearing film in this case is a 10 nm thick NaF film deposited over the electrodeposited metallic precursor stack comprising Cu, In, Ga with Cu/(In+Ga) molar ratio of about 0.8 and Ga/(Ga+In) molar ratio of about 0.3. A 1.5 micron thick Se layer was deposited over the NaF film and rapid thermal processing was used to react the species at 500 C. for 15 minutes. Solar cells were fabricated on the absorber layer by depositing a 0.1 micron thick CdS layer by chemical dip method followed by deposition of a ZnO window and Al fingers. The efficiency of the device shown in FIG. 8A is 8.6%. The I-V characteristics of FIG. 7B is for a device fabricated on another absorber layer (CIGS layer) grown using exactly the same procedures described above except that no NaF film was employed in this case. The efficiency of the device of FIG. 8B is only 1.92%. These results demonstrate the effectiveness of the present technique for doping the Group IBIIIAVIA absorber layers.

One method of depositing the dopant bearing film over a surface of a metallic precursor stack comprising Cu, In and Ga layers or over a surface of a precursor stack comprising Cu, In, Ga and a group VIA material layer such as a Se layer, is a wet deposition technique where the dopant is in a solution and gets deposited on the surface in the form of a thin dopant film. The goal of this approach would be to use a wet process to deposit a dopant layer that is free of water after drying. For this purpose it is preferable to use relatively non-hygroscopic materials as dopant-bearing materials. For example, NaF is soluble in water (4 grams in 100 gram of water). Therefore, a water solution of NaF may be prepared and delivered to the surface. After drying, a NaF layer free from hydration may be obtained on the surface because unlike some other sodium salts such as Na₂SeO₄, Na₂S etc., NaF does not form hydrated species. One other approach to obtain substantially water-free dopant-bearing films is to use an organic solvent in place of water for the preparation of a dopant-bearing solution. For example materials such as sodium azide, sodium bromide, sodium chloride, sodium tetrafluoroborate are soluble in ethanol to various degrees. Therefore, these materials may be dissolved in organic solvents such as ethanol and then deposited on the surface. Once organic solvent evaporates away, it leaves a substantially water-free layer of a dopant-bearing film. Another approach to obtain substantially water or hydride-free dopant-bearing films involves preparing an ink or paste of a dopant-bearing material using a solvent that does not dissolve the dopant-bearing material. For example, materials such as NaF, sodium bromate, sodium iodate, sodium carbonate, sodium selenite etc., are insoluble in ethanol. Therefore, nano-size particles of these dopant-bearing materials may be dispersed in ethanol forming an ink and then ink may be deposited on the surface to form a layer of the dopant-bearing material particles on the surface after ethanol evaporates away. The particle size of such a dispersion may preferably be in the range of 1-20 nm to be able to obtain a thin dopant-bearing film with thickness of 2-50 nm.

As described through the above examples, there are several approaches to form dopant structures on the precursor stacks. In a first case, the dopant-bearing film may be formed over a precursor stack comprising Cu, In and Ga layers and then a cap layer of a Se or a Group VIA material may be formed over the dopant-bearing film, as shown in FIG. 3A. Alternately, a Se layer may be deposited first over the precursor stack comprising Cu, In and Ga layers as a buffer layer, and then the dopant-bearing film may be deposited over the Se layer, as shown in FIG. 4A. Further, this may then be followed by another Se layer or cap layer deposition over the dopant-bearing film, as shown in FIG. 5A. In all three cases, the pre-absorber structures thus obtained are subsequently heat treated at elevated temperatures, typically in the range of 400-600 C. to form doped Cu(In,Ga)Se₂ absorber layers, as shown in FIGS. 3B, 4B and 5B. Additional Group VIA material such as Se may be provided during this annealing step. If S is also included in the reaction atmosphere then a Cu(In,Ga)(S,Se)₂ absorber layer may be obtained. The difference between the first case and the other two cases above is the placement of the dopant-bearing film within the overall dopant structure. In one case the dopant-bearing film is in physical contact with the metallic components (In, and/or Cu and/or Ga) of the precursor stack and starts to react/interact with these components as the temperature is raised, as shown in FIG. 3A. In the other cases, the dopant is in physical contact with the Group VIA material (such as Se) layer only, as shown in FIGS. 4A and 5A. Therefore, when the structure is heated, the dopant first diffuses in and mixes with the Se layer, especially at around 250 C. when the Se layer melts. Dopant then interacts with and diffuses into the metallic precursor stack as the precursor stack is also reacting with Se. Although the beneficial effect of the dopants such as an alkali metal is seen in both dopant structure approaches, a better CIGS(S) absorber layer surface morphology is obtained for films prepared using the dopant structure wherein the dopant-bearing film is deposited on top of the Se layer or the dopant was included within the Se layer, i.e. there is a buffer layer of a Group VIA material between the dopant-bearing film and the metallic precursor, as shown in FIGS. 4A and 5A. Dopant structures, shown in FIG. 3A, including a dopant-bearing film deposited directly on the precursor stack, followed by the Se layer, exhibit a higher density of In-rich nodules forming on the surface of the CIGS(S) absorber layer obtained after the anneal step. Nodules are non-uniformities that adversely affect the efficiency and yield of the process for large area solar cell fabrication.

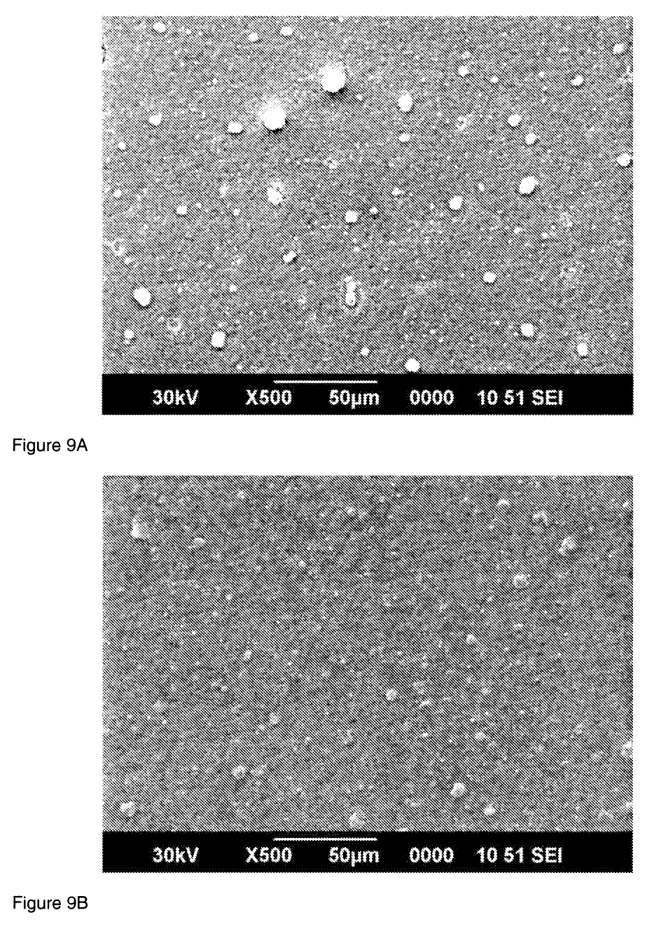

FIGS. 9A and 9B show scanning electron microscope (SEM) pictures of the surfaces of two CIGS absorber layers. The absorber layer shown in FIG. 9A was obtained by; i) electroplating metallic Cu, In and Ga layers to form a metallic precursor stack on a base, ii) evaporating a 5 nm thick NaF layer on the metallic precursor stack, iii) evaporating a 1.4 micrometers thick Se film as cap layer over the NaF layer, thus forming a pre-absorber stack, and iv) reacting the absorber stack at 500 C. for 20 minutes to form the absorber layer. The absorber layer in FIG. 9B, on the other hand, was obtained by; i) electroplating metallic Cu, In and Ga layers to form a metallic precursor on a base, ii) evaporating a 100 nm thick Se interlayer, as buffer layer, on the metallic precursor, iii) evaporating a 5 nm thick NaF layer over the Se buffer layer, iv) evaporating a 1.4 micrometers thick Se film, as cap layer, over the NaF layer, thus forming a pre-absorber stack, and v) reacting the absorber stack at 500 C for 20 minutes to form the absorber layer. As can be seen from these two figures the nodules (white formations) in FIG. 9A are eliminated in FIG. 9B. This reflects in device efficiencies of above 10% for solar cells fabricated on absorber films such as that shown in FIG. 9B. EDAX analysis of the nodules in FIG. 9A showed them to be rich in In.

In another embodiment the present invention utilizes vapor phase doping of CIGS type absorber layers. In this approach a precursor layer comprising at least one of a Group IB material, a Group IIIA material and a Group VIA material is annealed at around atmospheric pressure in presence of gaseous metal-organic Na, K or Li sources. As the CIGS absorber layer is formed during this annealing process, the dopant of Na, K or Li is included into the growing absorber film. Since there is no solid phase (such as NaF) that is included in the film, the present process is self limiting. In the case of solid Na sources, the amount of the solid source included into the CIGS absorber layer is critical. For example, 5-10 nm thick NaF may be effective in doping the CIGS absorber layer. However, 30-50 nm of NaF, if included in the CIGS absorber layer, may cause peeling and morphological problems due to too much Na. However, if a vapor phase Na source is used, whatever concentration is included in the absorber film gets included and any excess easily leaves the film as gas without deteriorating its properties. Some examples of Na sources include, but are not limited to sodium 2-ethylhexanoate NaOOCCH(C₂H₅)C₄H₉, sodium bis(2-Ethylhexyl) sulfosuccinate C₂₀H₃₇NaO₇S, sodium tertiary butoxide, sodium amide, sodium tertiary butoxide, sodium amide, hexamethyl disilazane, and the like. At least some of these materials are in liquid form and their vapors may be carried to the reaction chamber where CIGS absorber film is formed (or where an already formed CIGS film is annealed) by bubbling an inert gas (such as nitrogen) through them. Although the present invention is described with respect to certain preferred embodiments, modifications thereto will be apparent to those skilled in the art.

We claim:

1. A multilayer structure to form an absorber layer for solar cells, comprising:
a base comprising a substrate layer;
a substantially metallic precursor layer formed on the base, wherein the substantially metallic precursor layer comprises at least one Group IB and Group IIIA material; and
a dopant structure formed on the substantially metallic precursor layer, wherein the dopant structure includes a Group IA material.

2. The multilayer structure of claim 1, wherein the dopant structure is a dopant-bearing film comprising the Group IA material.

3. The structure of claim 2, wherein the dopant-bearing film has a thickness of 2-100 nm.

4. The multilayer structure of claim 1, wherein the dopant structure is a dopant carrier layer comprising a Group VIA material in addition to the Group IA material.

5. The structure of claim 4, wherein the Group VIA material comprises Se.

6. The structure of claim 4, wherein the dopant carrier layer has a thickness of 250-2600 nm.

7. The multilayer structure of claim 1, wherein the dopant structure is a dopant stack comprising a buffer layer formed on the substantially metallic precursor layer and a dopant-bearing film formed on the buffer layer, wherein the buffer layer comprises a Group VIA material and the dopant-bearing film comprises the Group IA material.

8. The structure of claim 7, wherein the Group VIA material comprises Se.

9. The structure of claim 7, wherein the buffer layer has a thickness of 50-500 nm, and the dopant-bearing film has a thickness of 2-100 nm.

10. The multilayer structure of claim 1, wherein the dopant structure is a dopant stack comprising a dopant bearing film formed on the substantially metallic precursor layer and a cap layer formed on the dopant-bearing film, wherein the dopant-bearing film comprises the Group IA material and the cap layer comprises a Group VIA material.

11. The structure of claim 10, wherein the Group VIA material comprises Se.

12. The structure of claim 10, wherein the dopant-bearing film has a thickness of 2-100 nm, and the cap layer has a thickness of 200-2000 nm.

13. The multilayer structure of claim 1, wherein the dopant structure is a dopant stack comprising a buffer layer on the substantially metallic precursor layer, a dopant-bearing film on the buffer layer, and a cap layer formed on the dopant-bearing film, wherein the buffer layer and the cap layer comprise a Group VIA material and the dopant-bearing film comprises the Group IA material.

14. The structure of claim 13, wherein the Group VIA material comprises Se.

15. The structure of claim 13, wherein the buffer layer has a thickness of 50-500 nm, the dopant-bearing film has a thickness of 2-100 nm, and the cap layer has a thickness of 200-2000 nm.

16. The structure of claim 1, wherein the Group IA material includes at least one of Na, K and Li.

17. The multilayer structure of claim 1, wherein the substantially metallic precursor layer comprises at least 80% metallic phase.

18. The multilayer structure of claim 1, wherein the at least one Group IB and Group IIIA material comprises Cu, In and Ga metals.

19. The multilayer structure of claim 1, wherein the base comprises a stainless steel substrate.

20. A process of forming a doped Group IBIIIAVIA absorber layer on a base, comprising:
depositing a substantially metallic precursor layer comprising at least one Group IB and Group IIIA material on the base;
forming a dopant structure on the precursor layer, the dopant structure comprising a dopant material including at least one of Na, K and Li; and
reacting the precursor layer and the dopant structure.

21. The process of claim 20, wherein forming the dopant structure comprises forming a dopant-bearing film on the substantially metallic precursor layer by depositing the dopant material.

22. The process of claim 21, wherein forming the dopant structure further comprises depositing a buffer layer made of a Group VIA material on the substantially metallic precursor layer prior to forming the dopant-bearing film.

23. The process of claim 22, wherein the Group VIA material comprises Se.

24. The process of claim 22, wherein forming the dopant structure further comprises depositing a cap layer made of the Group VIA material on the dopant-bearing film.

25. The process of claim 24, wherein the Group VIA material comprises Se.

26. The process of claim 22 wherein depositing the buffer layer comprises vapor depositing the Group VIA material.

27. The process of claim 22 wherein depositing the buffer layer comprises electroplating the Group VIA material.

28. The process of claim 21, wherein forming the dopant structure further comprises depositing a cap layer made of a Group VIA material on the dopant-bearing film.

29. The process of claim 28, wherein the Group VIA material comprises Se.

30. The process of claim 28 wherein depositing the cap layer comprises vapor depositing the Group VIA material.

31. The process of claim 21 wherein depositing the dopant-bearing film comprises vapor depositing the dopant material.

32. The process of claim 21 wherein depositing the dopant-bearing film comprises dip coating the dopant material.

33. The process of claim 20, wherein forming the dopant structure comprises forming a dopant carrier layer on the substantially metallic precursor layer by co-depositing a Group VIA material and the dopant material.

34. The process of claim 33 wherein co-depositing comprises vapor depositing the dopant material and the Group VIA material together.

35. The process of claim 33, wherein the Group VIA material comprises Se.

36. The process of claim 20, wherein reacting comprises annealing at a temperature range of 450-550 C.

37. The process of claim 36, wherein reacting comprises annealing for 15-30 minutes.

38. The process of claim 20 further comprising supplying a gaseous environment containing at least one of Se and S while reacting.

39. The process of claim 20, wherein the at least one Group IB and Group IIIA material comprise Cu, In and Ga metals.

40. The process of claim 20, wherein depositing the substantially metallic precursor layer comprises electroplating the at least one Group IB and Group IIIA material on the base. cap layercap layer
